(19) United States
(12) Patent Application Publication
(10) Pub. No.: US 2007/0002619 A1
(43) Pub. Date: Jan. 4, 2007

(54) BISTABLE MULTIVIBRATOR WITH NON-VOLATILE STATE STORAGE

(76) Inventors: TIM SCHOENAUER, Feldkirchen (DE); Michael Kund, Tuntenhausen (DE); Thomas Niedermeier, Rosenheim (DE); Joerg Berthold, Munich (DE)

Correspondence Address: PATTERSON & SHERIDAN, LLP;Gero McClellan / Infineon Technologies, 3040 POST OAK BLVD.,, SUITE 1500, HOUSTON, TX, 77056, US

(21) Appl. No.: 11/427,339

(22) Filed: Jun. 28, 2006

(30) Foreign Application Priority Data
Jun. 28, 2005 (DE) DE102005030142.8

(51) Int. Cl. G11C 11/34

(52) U.S. Cl. 365/185.08; 365/163

(57) ABSTRACT

The non-volatile memory cell has a volatile memory means for storing an item of binary information. Furthermore, the memory cell comprises only a single programmable resistance element for non-volatile saving of the stored information and a means for saving the information in the resistance element. A means for retrieving the saved information is additionally present.

### CROSS-REFERENCE TO RELATED APPLICATIONS

This application claims foreign priority benefits under 35 U.S.C. §119 to co-pending German patent application number 10 2005 030 142.8, filed Jun. 28, 2005. This related patent application is herein incorporated by reference in its entirety.

### BACKGROUND OF THE INVENTION

1. Field of the Invention

Embodiments of the invention relate to a non-volatile memory cell having a volatile memory means, including, for example, a bistable multivibrator, and a resistance element having a binary programmable resistance value for non-volatile saving of the binary information stored in the volatile memory means. Embodiments of the invention additionally relate to a shift register constructed from non-volatile memory cells of this type.

2. Description of the Related Art

As the number of power-loss-sensitive applications of monolithic integrated circuits increases, for example, in the area of mobile applications, and as the power loss consumption rises on account of increasing complexity of these circuits, some temporarily unused circuit blocks may be operated with a reduced power loss in a so-called power-down mode, or even to shut them down completely. For some applications it the latches or flip-flops used for state storage in sequential circuit blocks, for example, logic blocks, may save their storage state upon transition from the normal operating mode to the power-down mode so that the respective circuit block is in its previous state again after the transition from the power-down mode to the normal operating mode and the retrieval of the saved storage states. Flip-flops or latches of this type which are provided with bistable multivibrators for volatile storage and also with an additional memory for saving and retention of the storage state during operation in the power-down mode, are also referred to as retention flip-flops or retention latches.

This concept of saving the storage states in the power-down mode can also be utilized in a similar manner for other circuit applications which use bistable multivibrators for data storage, for example for SRAM (SRAM: static random access memory) or for PLD configuration memories (programmable logic devices).

In the implementation of such retention flip-flops or retention latches (e.g., a single multivibrator), two types of retention flip-flops or retention latches are known in principle in the prior art: firstly memory cells which are implemented purely using CMOS technology (complementary metal oxide semiconductor) and secondly memory cells which are based on a combination of CMOS technology and non-volatile memory technology.

In the implementation purely using CMOS technology, a second supply voltage may be provided in addition to the primary supply voltage, and, in contrast to the primary supply voltage is not switched off during the power-down mode. A retention flip-flop of this type is disclosed in the documents U.S. Pat. No. 5,473,571 and “A 1-V High-speed MTCMOS Circuit Scheme for Power-down Application Circuits”, Shigematsu et al., Journal of Solid State Circuits, June 1997, pages 861 to 869. In this case, an additional latch fed by means of the second supply voltage is used to save the storage state of the flip-flop during the power-down mode. If the flip-flop is fed with the primary supply voltage again after the power-down mode, the saved storage state can be transferred back again into the circuit section of the flip-flop that is operated with the primary supply voltage. A retention flip-flop of this type is often referred to as a balloon flip-flop in the prior art, the latch operated with the second supply voltage being referred to as a balloon latch.

The prior art (thus, by way of example US 2003/0188241 and US 2004/051574) discloses a multiplicity of retention flip-flops which are based on the balloon flip-flop described in the document cited above and have a reduced area usage or a higher data rate.

Retention flip-flops based purely on CMOS technology may have some disadvantages. For example, a property of pure CMOS technology may be the storage volatility thereof. For example, in some cases, it may be used solely for volatile data storage. If the supply voltage is switched off, the data content may be lost. For this reason, a second supply voltage may be provided, which remains active in the power-down mode. This may cost additional chip area since the second supply voltage may be distributed on the chip. Moreover, a balloon flip-flop of this type may occupy a larger chip area in comparison with a customary flip-flop without data saving. The additional area of a flip-flop of this type typically may correspond to more than 50% of the chip area of a customary flip-flop. Moreover, a leakage current may flow during the power-down mode in the balloon latch, said leakage current being associated with an additional power loss during the power-down mode. The leakage current can be reduced by using transistors having a threshold voltage with a large magnitude.

In some cases, the abovementioned disadvantages may be reduced by using non-volatile memory technologies in the implementation of a retention flip-flop.

So-called PCM technology (phase change memory) may be suitable for this purpose, this technology being briefly described below. PCM technology is currently the focus of intensive research, for example, in connection with matrix memories. PCM technology makes it possible to program the value of a resistance element, the programming being non-volatile and thus being maintained when the supply voltage is switched off. PCM technology is based on changing the phase state of a chalcogenide glass thermally in a reversible manner between the amorphous state and the crystalline state. In this case, the resistivity of a resistance element comprising chalcogenide glass is greater in the amorphous state than in the polycrystalline state. The change in the phase state is brought about by heat generated by means of a current pulse through the resistance element. In this case, the duration and the current intensity of the current pulse determine whether the resistance element subsequently has a high or low resistance value.

FIG. 1 illustrates two current pulses 1 and 2 for the programming of a resistance element of this type. The resistance element is converted into the amorphous state with a resistance value of 1 MΩ by means of the current pulse 1 having a relatively high current intensity of 200 μA and a relatively short pulse duration of 20 ns, while the resistance element is transformed into the polycrystalline state with a resistance value of 10 kΩ by means of the current pulse 2 having a relatively low current intensity of 50 μA and a relatively long pulse duration of 50 ns.

One advantage of PCM technology over other non-volatile memory technologies is that a reduction in the dimensions of the storing elements may be provided. The smaller the structures used, the lower the used current intensity of the current pulse that initiates the phase change. What is more, PCM resistance elements can be realized in the upper layers of a CMOS semiconductor process so that the resistance elements can be arranged above the transistors, for example, in each case directly above the transistors assigned to a memory cell.

The document US 2004/0141363 A1 describes the application of PCM technology in connection with SRAM memory cells. Customary SRAM memory cells in each case comprise a bistable multivibrator in the form of two cross-coupled inverters for volatile information storage, the binary information corresponding to the potential value of the two output nodes of the two inverters. In the case of the SRAM memory cell described in this document, a resistance element is additionally connected to each of the two nodes via a switchable coupling NMOS transistor, the two resistance elements being connected to a common node (“plate line”) with the potential PL. The two coupling transistors functioning as switches are controlled on the gate side by means of a digital signal CL (common control signal line).

In order to save the binary information stored in the bistable multivibrator, the two resistance elements are firstly put into the high-resistance state by means of a suitable pulse sequence of the signals CL and PL and current pulses associated therewith (phase change reset operation or PC reset operation). Subsequently, by means of a suitable pulse of the signal CL, precisely a single one of the two resistance elements is programmed to a low resistance value (save operation). In this case, which of the two resistance elements is programmed depends on the state of the two output nodes. The differentiation between the PC reset operation (resetting to the high-resistance state) and the save operation (programming of the low-resistance state) may be made on the basis of the pulse length or the pulse amplitude.

To retrieve the binary information saved in the two resistance elements, the coupling transistors are turned on during the pulse duration by means of a suitable pulse of the signal CL. The potential PL is driven up in ramped fashion to the supply voltage. Depending on the resistance value of the two resistance elements, the two output nodes are subjected to charge reversal at different speeds. The supply voltage of the inverters is simultaneously switched on, so that said inverters toggle according to the charge state of the precharged output nodes.

The SRAM memory cell described above may have some disadvantages:

Firstly, the coupling transistors used are NMOS transistors, which, although they can switch the ground potential without a voltage drop, nevertheless cannot transfer the entire positive voltage swing at the level of the positive supply voltage. Consequently, programming errors may occur, under certain circumstances, when saving the binary information. This can admittedly be avoided by using two transmission gates comprising an NMOS transistor and a PMOS transistor instead of two coupling transistors. In a transmission gate, the NMOS transistor switches the ground potential without any losses, while the PMOS transistor switches the positive supply potential without any losses. However, the use of transmission gates may increase the number of transistors by two transistors.

In some cases, the different resistance programming during the PC reset operation and the save operation may be achieved with the aid of a variation of the pulse length or the voltage amplitude. In the case of different voltage amplitudes a second supply voltage may be provided, while in the case of different pulse lengths circuitry outlay may be devoted to the generation of the different pulse lengths.

Furthermore, providing the retrieval of the saved information in a robust manner may be difficult. For example, the sequence that is used for retrieving the saved information and comprises the ramped, slow driving up of the potential PL, and, synchronized with this the ramped, fast driving up of the supply voltage of the bistable multivibrator, and the pulse of the signal CL for switching on the coupling transistors, may use a high circuitry outlay. It may be provided in this case that the read-out process is sufficiently robust and the resistance information is not erased during read-out (destructive read-out).

Furthermore, the potentials of the storage nodes of the bistable multivibrator are totally undefined prior to the retrieval of the saved information. This may have the effect that the bistable multivibrator does not switch into the desired state after switch-on. During the retrieval of the saved information, one of the two resistance elements is at high resistance, so that the potential of the storage node connected to said resistance element changes slightly during the driving up of the signal PL. For the case where this node is not at the ground potential during the retrieval of the saved information, the change in potential may be too small to enable the multivibrator to be switched into the desired state. The two inverters of the multivibrator operate against one another in this case.

Moreover, the use of two resistance elements in the layout of the memory cell proves to be problematic. Since these resistance elements are typically arranged in the upper metal layers, the connections between the resistance elements and the rest of the circuit elements occupy a relatively large part of the metal layers provided for wiring.

### SUMMARY OF THE INVENTION

One embodiment of the invention provides an alternative non-volatile memory cell to the non-volatile memory cell known from the prior art, in the case of which alternative non-volatile memory cell, the non-volatile saving of information is effected by means of a resistance programming, wherein the circuitry outlay may be reduced in comparison with the prior art. Moreover, embodiments of the invention provide a shift register comprising a plurality of non-volatile memory cells.

The non-volatile memory cell according to one embodiment of the invention has a volatile memory means with one or a plurality of storage nodes for storing an item of binary information in the form of the potential value of a first storage node. A bistable multivibrator in the form of two cross-coupled CMOS inverters may be provided for this. Furthermore, the non-volatile memory cell may include a single resistance element having a binary programmable resistance value for non-volatile saving of the binary information stored in the volatile memory means. Furthermore, the non-volatile memory cell may include a means for saving the binary information in the resistance element. This means is configured in such a way that the resistance value is programmed in a manner dependent on the potential of the first storage node. Moreover, a means for retrieving the binary information saved in the form of the resistance value may be provided.

The non-volatile memory cell according to one embodiment of the invention is based on the concept for binary information saving. In some cases, the two resistance elements described in the prior art need not be used and circuitry outlay may thereby be reduced. Embodiments of the invention may provide a single resistance element for this task, each resistance value of said resistance element being assigned one of the two states of the volatile memory means.

In some cases, by using a single resistance element for saving the binary information, it is possible to reduce the circuitry outlay for the non-volatile memory cell. For example, the use of a single resistance element may be used for the layout of the memory cell since a single resistance element, which may be arranged between two upper metal layers, may be connected. In some cases, a small part of the metal layers provided for the wiring is occupied thereby. Moreover, the use of a single resistance element reduces the number of circuit elements which serve for programming and retrieving the saved information.

The resistance element may be a PCM resistance element having a large resistance value in the amorphous state and a small resistance value in the polycrystalline state. However, alternative memory technologies may be used in which, as in PCM technology, the information is stored on the basis of the resistance programming of a resistance element. As an example of an alternative memory technology of this type, reference shall be made here to PMC technology (programmable metallization cell). PMC technology and PCM technology are generally combined under the term “ionic memory”.

The means for retrieving the binary information may be configured in such a way that it defines the potential value of a second storage node—which may not be different from the first storage node—of this memory cell, that is to say that the first storage node and the second storage node may be the same or different nodes. As an alternative, it may be provided that this means defines the storage node of another identical memory cell in a manner dependent on the resistance value. In the second case, the information saved in the form of the resistance value is transferred into another memory cell instead of into the original memory cell.

In one embodiment, the means for retrieving the binary information may include a means for initializing the potential of the second storage node with a fixed value, for example with the ground potential (VSS) or the positive operating voltage potential (VDD). It is thereby possible to put the second storage node into a defined state prior to the actual retrieval of the binary information. This measure prevents the retrieval of the binary information from being influenced by the state of the second storage node prior to the retrieval. For the case where the resistance element is at high resistance during the retrieval of the saved information, the potential of the second storage node is changed slightly by means of the resistance element during the retrieval. If the state of the second storage node is undefined, the change in potential, proceeding from an unfavorable potential value, is possibly too small to put the volatile memory element into the saved state. According to one embodiment of the invention, however, the state of the second storage node is initialized with a known fixed value, so that the volatile memory element toggles reliably into the correct state independently of the previous state of the second storage node. The robustness during the retrieval of the saved information is thus increased with the aid of this measure.

For the case where the volatile memory means comprises two cross-coupled inverters and the potential of the second storage node can be initialized, the output of that inverter which drives the second storage node may be switched in high-resistance fashion or may be decoupled from the second storage node. The high-resistance output state is also referred to as a tristate state. The output is switched in high-resistance fashion or is decoupled from the second storage node if the second storage node is initialized with a fixed value prior to the actual retrieval of the saved information.

In this case, the two cross-coupled inverters may be CMOS inverters, each having an NMOS transistor and a PMOS transistor. In a first configuration of the non-volatile memory cell, the means for initializing the potential of the second storage node, in the case of initializing the potential, connects the second storage node to the ground node, while the output of the inverter that can be switched in high-resistance fashion is switched in high-resistance fashion. In an alternative second configuration of the non-volatile memory cell, the means for initializing the potential of the second storage node, in the case of initializing the potential, connects the second storage node to the positive operating voltage node instead of the ground node. In the inverter that can be switched in high-resistance fashion on the output side, in both alternative configurations, a single additional transistor may be provided for switching the inverter output into the high-resistance state. In the first configuration, said additional transistor is an NMOS transistor, the source-drain path of which is arranged between the ground node and the source terminal of the NMOS transistor of the same inverter, and which decouples the ground node from the source terminal of the NMOS transistor of the inverter in the case of a high-resistance output. The alternative configuration involves a PMOS transistor, the source-drain path of which is arranged between the positive operating voltage node and the source terminal of the PMOS transistor of the same inverter, and which decouples the positive operating voltage node from the source terminal of the PMOS transistor of the inverter in the case of a high-resistance output.

In a typical implementation of an inverter output with tristate capability, two additional transistors are generally provided in the prior art, the first additional transistor and the second additional transistor usually decoupling the high-resistance output from the positive operating voltage node and from the ground node, respectively. According to one embodiment of the invention, one of the two additional transistors is dispensed with since the second storage node is initialized to VSS or VDD. Assuming that the inverters are active, the input of the inverter with tristate capability may be at VDD or VSS. It may thus be possible to avoid the activation of the PMOS transistor or the NMOS transistor of the CMOS inverter. An additional transistor which mutes the PMOS transistor or the NMOS transistor of the CMOS inverter on the output side may therefore, in some cases, not be utilized.

The means for saving the binary information may include a means for initializing the resistance value to a specific value of the two programmable values. By way of example, prior to the actual saving of the information stored in the volatile memory element, the resistance element is firstly put into the high-resistance state.

According to one embodiment of the non-volatile memory cell, the means for saving the binary information comprises a first switch, for example, in the form of a MOS transistor. This switch connects the first storage node to the resistance element (closed switch position) or decouples the first storage node from the resistance element (opened switch position). In this case, the first switch, with a closed switch position, serves for programming the resistance value in a manner dependent on the potential of the first storage node (save operation). With a closed switch position, a current thus flows through the resistance element in the case of one of the two potential states (for example, VSS) of the first storage node, which current reprograms the resistance element. If the other potential state is present, the resistance element is not reprogrammed.

The means for retrieving the saved binary information may include a second switch, for example, in the form of a MOS transistor. This switch, with a closed switch position, connects the second storage node to the resistance element. With an opened switch position, this switch decouples the second storage node from the resistance element. With a closed switch position, the second switch serves for retrieving the saved information (restore operation). If the second switch is closed, the second storage node is subjected to charge reversal in a manner dependent on the previously programmed resistance value. In this case, the binary information is produced on the basis of the potential of the second storage node at the end of the charge-reversal process.

In one embodiment, two separate switches may be used for the first and the second switch. This results in an additional degree of freedom in the configuration of the non-volatile memory cell. Given suitable dimensioning of the first and of the second switch, the currents can in each case be set optimally with regard to the save operation and the restore operation. This makes it possible to prevent, for example, a situation in which such a large current flows during the restore operation that the resistance element is reprogrammed (destructive read-out).

By means of a suitable choice of the transistor type (N- or P-MOS) for implementing the first or respectively the second switch, it is furthermore also possible for the voltage drop across the programmable resistance element to be chosen differently in the case of a closed first or respectively second switch. Thus, for example, in the case of an implementation with complementary transistors, it is possible to provide that the full voltage swing is dropped across the programmable resistance element during the save operation, while the voltage swing is reduced by the threshold voltage of the turned-on transistor during the restore operation. This makes it possible, on the one hand, to reduce the power consumption and the thermal heating of the resistance element during the restore operation; on the other hand, it may thereby possible to provide, in the read case, that the voltage which reprograms the resistance element is not exceeded.

In one embodiment, the means for initializing the resistance value may include a third switch, for example, in the form of a MOS transistor. The latter, with a closed switch position, connects the resistance element to a first node having a fixed potential, for example to VSS, and, with a closed switch position decouples the resistance element from the first node having a fixed potential. If the third switch is closed for a certain duration, a current pulse flows through the resistance element and initializes the resistance element with a defined resistance value (PC reset operation).

In one embodiment, the first switch for carrying out the save operation and the third switch for carrying out the PC reset operation may be two separate switches. This may provide in an additional degree of freedom in the configuration of the non-volatile memory cell. Given suitable dimensioning of the first and the third switch, the currents for the save operation and the PC reset operation may be set differently. Thus, a high resistance value may be set during the PC reset operation in the case of a high current intensity, while a small resistance value is programmed during the save operation depending on the potential of the first storage node in the case of a low current intensity. An additional supply voltage for the variation of the current intensity may therefore not be utilized. Under certain circumstances, in order to simplify the circuit, the pulse duration may be to be identical during the save operation and the PC reset operation and for the resistance value to be produced solely on the basis of the current intensity of the current respectively flowing through the resistance element.

In one embodiment, the means for initializing the potential of the second storage node may include a fourth switch, for example, in the form of a MOS transistor. The latter, with a closed switch position, connects the second storage node to a second node having a fixed potential (for example VSS) while the switch, with an opened switch position, decouples the second storage node from the second node having a fixed potential. With a closed switch position, with the aid of the fourth switch, the second storage node can be put at a predefined potential, for example VSS, prior to the actual retrieval of the saved information, so that the restore operation is not influenced by the original state of the second storage node.

In an alternative embodiment, the fourth switch may be used directly for the retrieval of the saved information instead of for the initialization of the second storage node. If the second and fourth switches are closed, the resistance element, the closed second switch and the closed fourth switch act as a voltage divider. In this case, the potential at the second storage node between the fourth and second switches is established in a manner dependent on the resistance value of the resistance element and thus, according to the saved binary information. If the saved binary information is retrieved by means of the voltage divider, as described above, the temporal synchronization of the switch position of the second and fourth switches may be simplified. In this embodiment, the second and fourth switches can be controlled by means of the same signal. In this case, in order to restrict the power loss consumption and in order to prevent a destructive read-out, the current in the voltage divider may be limited. This may be provided by choosing the resistance Ron of the second switch with a sufficient magnitude in the case of the closed switch position.

In one embodiment, the volatile memory means may be reset into a specific state, that is to say the volatile memory means may include a reset input. In this case, the fourth switch may be used for both initializing the second storage node and directly reading out the saved information and also for resetting the memory means. The fourth switch may be thus doubly utilized, so that the number of switches used may be reduced by one switch.

In one implementation of the non-volatile memory cell according to one embodiment of the invention, the first node and the second node having a fixed potential correspond to the ground node, while the resistance element is connected to the positive operating voltage node by its second terminal. In this case, the first, second, third and fourth switches are implemented in the form of an NMOS transistor, PMOS transistor, NMOS transistor and NMOS transistor, respectively.

In one embodiment, the first node and the second node may have a fixed potential corresponding to the positive operating voltage node. In this case, the resistance element is connected to the ground node. The first, second, third and fourth switches are implemented in the form of a PMOS transistor, NMOS transistor, PMOS transistor and PMOS transistor, respectively.

The non-volatile memory cell may include a master-slave flip-flop having a master stage and a slave stage. In this case, the volatile memory means comprises a total of two bistable multivibrators, the master stage comprising the first bistable multivibrator and the slave stage comprising the second bistable multivibrator. In this case, the programmable resistance element can be assigned to the master stage or to the slave stage, that is to say the binary information of the master stage or of the slave stage is saved in the resistance element and subsequently read into the master or slave stage again. As an alternative, the binary information from the slave stage (alternatively: master stage) may be saved in the resistance element and subsequently be read into the master stage (alternatively: slave stage). In this case, the first storage node and the second storage node are nodes of different multivibrators of the volatile memory means.

As an alternative to this a master-slave flip-flop comprising a single bistable multivibrator may be realized by means of the non-volatile memory cell. In this case, the master stage may include the bistable multivibrator. The slave stage in this case comprises the resistance element, the means for saving the binary information and the means for retrieving the binary information, that is to say the binary information of the slave stage is stored in the resistance element instead of in a bistable multivibrator. One possible advantage of a master-slave flip-flop of this type is the smaller area usage in comparison with customary master-slave flip-flops comprising two bistable multivibrators.

Analogously, instead of storing the binary information of the slave stage, the binary information of the master stage may be stored in a resistance element, the bistable multivibrator being dispensed with in the master stage in this case.

One embodiment of the invention is directed at a shift register comprising a plurality of series-connected non-volatile master-slave flip-flops each comprising one bistable multivibrator. In one embodiment, as described above, the binary information of the slave stage is stored in the resistance element instead of in a bistable multivibrator. In this case, for each non-volatile memory cell of the shift register, the means for retrieving the binary information in each case defines the potential value of the second storage node of the memory cell connected downstream of the respective memory cell in a manner dependent on the resistance value.

A shift register of this type in which the slave stage of a master-slave flip-flop is realized by means of the non-volatile resistance element, is significantly more efficient in terms of area than customary shift registers which comprise two multivibrators in each case per master-slave flip-flop. The shift register according to one embodiment of the invention is suitable, for example, for reading a sequence of binary configuration data serially into a semiconductor component. In this case, the binary configuration data can be stored in the resistance elements in an efficient manner in terms of power loss. Moreover, the configuration data are stored in the resistance elements in a non-volatile manner, so that the semiconductor component retains the configuration data even when the semiconductor component is switched off.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows two idealized current pulses for the programming of PCM resistance elements;

FIG. 2 shows a simplified basic circuit diagram for a first plurality of exemplary embodiments of the non-volatile memory cell according to one embodiment of the invention;

FIG. 3 shows an exemplary embodiment of the non-volatile memory cell according to one embodiment of the invention which is based on FIG. 2;

FIG. 4 shows a first exemplary embodiment of the cross-coupled inverters according to one embodiment of the invention;

FIG. 5 shows a second exemplary embodiment of the cross-coupled inverters according to one embodiment of the invention;

FIG. 6 shows a simplified basic circuit diagram for a second plurality of exemplary embodiments of the non-volatile memory cell according to one embodiment of the invention;

FIG. 7 shows a simplified basic circuit diagram for a third plurality of exemplary embodiments of the non-volatile memory cell according to one embodiment of the invention;

FIG. 8 shows a first exemplary embodiment of the memory cell according to one embodiment of the invention in the form of a D-type flip-flop;

FIG. 9 shows a signal diagram for relevant signals from FIG. 8 according to one embodiment of the invention;

FIG. 10 shows a second exemplary embodiment of the memory cell according to one embodiment of the invention in the form of a D-type flip-flop;

FIG. 11 shows an exemplary embodiment of the shift register according to one embodiment of the invention; and

FIG. 12 shows a signal diagram for relevant signals from FIG. 11 according to one embodiment of the invention.

### DETAILED DESCRIPTION OF THE PREFERRED EMBODIMENT

FIG. 2 illustrates a simplified basic circuit diagram for a plurality of exemplary embodiments of the non-volatile memory cell according to one embodiment of the invention. Clock-controlled switches that are possibly provided for the realization of a clock-controlled latch are not illustrated in FIG. 2. The memory cell comprises a bistable multivibrator for volatile storage of an item of binary information, which is realized by means of two cross-coupled inverters INV1 and INV2. The binary information is stored in the form of the potentials of the storage nodes K1 and K2. The memory cell furthermore comprises a binary programmable resistance element R1 (e.g., a PCM resistance element) for saving the information stored in the multivibrator in the event of a transition to the power-down mode. Two switches SW3 and SW4 are furthermore provided for saving the binary information, the switch SW3 serving for the PC reset operation and the switch SW4 serving for the save operation. Two switches SW1 and SW2 are used for retrieving the information stored in the resistance element R1. The two nodes A and B constitute the data input and the data output of the memory cell. When the memory cell is used in a flip-flop, a clocked transmission gate may be connected upstream of the input (not illustrated). Moreover, in this case there may be a transmission gate situated in the feedback between the cross-coupled inverters INV1 and INV2. If the memory cell is used in an SRAM, the two nodes A and B are connected to differential bit lines via two coupling transistors (not illustrated). The nodes C, D and E have a fixed potential (either VSS or VDD).

The output of the inverter INV2 can be put into the tristate state by means of the digital signal restore_n. If the signal restore_n is low, the inverter INV2 drives the storage node K2; otherwise the output is at high resistance. As an alternative the output of the inverter INV2 could also be decoupled from the storage node K2 via an additional transmission gate (not illustrated).

Table 1 specifies the configuration of the non-volatile memory cell illustrated in FIG. 2 for four different exemplary embodiments. Switches which are realized as NMOS transistors are closed if the respective gate potential is at VDD. Conversely, switches which are implemented as PMOS transistors are closed when the respective gate potential is at VSS.

TABLE 1

| | Node | Node | Node | Node | Node | Switch | Switch | Switch | Switch |
|---|---|---|---|---|---|---|---|---|---|
| Embodiment | A | B | C | D | E | SW1 | SW2 | SW3 | SW4 |
| 1 | Input | Output | VSS | VDD | VSS | PMOS | NMOS | NMOS | NMOS |
| 2 | Output | Input | VSS | VDD | VSS | PMOS | NMOS | NMOS | NMOS |
| 3 | Input | Output | VDD | VSS | VDD | NMOS | PMOS | PMOS | PMOS |
| 4 | Output | Input | VDD | VSS | VDD | NMOS | PMOS | PMOS | PMOS |

FIG. 3 illustrates an exemplary embodiment of the memory cell according to one embodiment of the invention as shown in FIG. 2, this exemplary embodiment corresponding to embodiment 1 in Table 1. In this case, the node A serves as a data input, while the node B constitutes the data output. The nodes C and E are at the ground potential VSS and the node D is connected to the positive operating voltage potential VDD. The switches SW2, SW3 and SW4 are implemented as NMOS coupling transistors, while the switch SW1 is embodied as a PMOS coupling transistor.

The functioning of the memory cell illustrated in FIG. 2 is explained by way of example on the basis of embodiment 1 according to FIG. 3.

a) Normal Operation:

During normal operation, the signal restore_n is high, the switches SW1, SW2, SW3 and SW4 are open and the memory cell operates like a customary latch.

b) Saving the Binary Information:

In order to save the state information of the multivibrator in the resistance element R1, firstly the switch SW3 is closed, that is to say that the gate potential of SW3 changes to high. This initiates a current flow via R1 and SW3, which serves to put the resistance element R1 into a defined state, for example into the amorphous state having a high resistance value (PC reset operation). The switch SW4 is subsequently closed, that is to say that the gate potential of SW4 changes to high. The potential of the storage node K1 determines whether a current flows through the resistance element R1 and the switch SW4 (save operation). If the storage node K1 is at VDD, no current flows, since the potentials of the nodes K1 and D correspond to one another. If, by contrast, the storage node K1 is at VSS, a current flows through the resistance element R1 since the potentials of the nodes K1 and D are different in this case. Said current is dimensioned such that the resistance element R1 is reprogrammed thereby, that is to say that in this case the resistance element R1 changes to the polycrystalline state having a low resistance value if the resistance element was initially initialized at high resistance. Depending on the storage content of the memory cell, the resistance element R1 thus has a high or a low resistance value after the storage content has been saved.

c) Retrieving the Saved Information:

In order to retrieve the information saved in the resistance element R1 during the power-down mode (restore operation) firstly the switch SW2 is closed by virtue of the gate potential of SW2 being changed over to high. The storage node K2 is thereby put at a defined potential (here, VSS). The signal restore_n is then switched to low, so that the output of the inverter INV2 acquires high resistance. At the same time, the switch SW1 is closed for a specific time duration, so that the storage node K2 is subjected to charge reversal in a manner dependent on the resistance value of the resistor R1, while the switch SW2 is opened again. The time duration is chosen in such a way that when the time duration has elapsed, the potential of the storage node K2 approximately corresponds to VDD if the resistance element R1 is at low resistance, or the potential of the storage node K2 has remained approximately at VSS if the resistance element R1 is at high resistance. After the switch SW1 has been opened, the signal restore_n is switched to high, so that the bistable multivibrator is activated. The multivibrator then toggles according to the potential at the storage node K2. The retrieval of the saved information may be carried out both in the event of changeover from the power-down mode to normal operation and during normal operation.

As an alternative to the procedure described above, the saved information may also be retrieved by means of a voltage divider formed from the series circuit comprising the resistance element R1 and the switches SW1 and SW2, if the switches SW1 and SW2 are closed. Given suitable dimensioning of the resistance element R1, and of the switch resistances R_{on,SW1} and R_{on,SW2} with the switches SW1 and SW2 respectively closed, it is possible for the potential of the storage node K2 to be either above VDD/2 or below VDD/2, if the resistance element R1 has high resistance or low resistance, respectively. By way of example, it is possible for this purpose to choose the switch resistance R_{on,SW1} in the range of from 10 kΩ to 25 kΩ and the switch resistance R_{on,SW2} in the range of from 100 kΩ to 250 kΩ, with the resistance value of the resistance element R1 in the high-resistance state and in the low-resistance state corresponds to 10 MΩ and 10 kΩ, respectively. At the output of the inverter INV1, the potential switches to VDD or VSS if the potential of the storage node K2 is less than or greater than VDD/2, respectively. If the signal restore_n is switched to VDD, the impressed information is accepted on the part of the multivibrator. In addition, the switches SW1 and SW2 are opened.

The alternative procedure when retrieving the stored information may provide that the temporal synchronization of the signals controlling the switches and of the signal restore_n is simplified. In this case, the current in the voltage divider may be noted in order to restrict the power loss consumption and in order to prevent a destructive read-out. This can be provided, for example, by choosing the resistance R_{on,SW2} of the switch SW2 to be sufficiently high.

The memory cells according to one embodiment of the invention as illustrated in FIG. 2 and FIG. 3 may provide a multiplicity of advantages over the non-volatile memory cell described in the document US 2004/0141363 A1:

1. According to one embodiment of the invention a single resistance element may be used for non-volatile saving. This reduces the circuitry outlay for the non-volatile memory cell. For example, the use of a single resistance element may provide for the layout of the memory cell where a single resistance element, which may be arranged between two upper metal layers, is to be connected. A small part of the metal areas provided for the wiring may be occupied thereby. Moreover, the use of a single resistance element reduces the number of circuit elements which serve for the programming and the retrieval of the saved information.

2. In contrast to the memory cell known from the prior art, in the configuration of the transistors the switches SW1 and SW4 in accordance with Table 1, the entire voltage swing can be transferred without having to use transmission gates. In this case that the ground potential VSS may be switched via the NMOS transistors, while the positive potential VDD is switched via the PMOS transistors.

3. The circuit concept according to one embodiment of the invention permits the stored information saved in the resistance element R1 to be able to be retrieved even during operation of the multivibrator, that is to say when the multivibrator is supplied with operating voltage. It is not possible in the case of the circuit described in the document US 2004/0141363 A1.

4. The saving and retrieval of the binary information may be significantly more robust in the case of the circuit concept according to one embodiment of the invention since the nodes, that is to say the storage nodes K1 and K2, have a defined potential during the entire sequence of saving and retrieving the binary information.

5. Furthermore, in contrast to the prior art, two different switches SW4 and SW1 are used for the save operation and the actual restore operation. This results in an additional degree of freedom in the configuration of the non-volatile memory cell. By dimensioning the switch SW1 with a sufficiently high resistance, it is possible to restrict the maximum current when retrieving the binary information in such a way that a destructive read-out is prevented.

6. Furthermore, in contrast to the prior art, two different switches SW3 and SW4 are used for the reset operation and the save operation as well. The currents for the save operation and the PC reset operation can be set differently as a result. Thus, a high resistance value may be set during the PC reset operation in the case of a high current intensity, while a small resistance value is programmed during the save operation depending on the potential of the storage node K1 in the case of a low current intensity. An additional supply voltage for the variation of the current intensity may therefore, in some cases, not be needed. Under certain circumstances, in order to simplify the circuit, the pulse duration to be identical during the save operation and the PC reset operation and for the resistance values may be produced solely on the basis of the current intensity of the current respectively flowing through the resistance element.

7. Furthermore, in the case of the memory cell according to one embodiment of the invention, in accordance with FIG. 2, different storage nodes are read from and written to during the save operation and the restore operation. This degree of freedom can be utilized in the realization of a master-slave flip-flop or a shift register—as will be described below.

In comparison with a customary edge-triggered latch, an edge-triggered latch based on the memory cell illustrated in FIG. 2 may use, as additional circuitry outlay, a single programmable resistance element, four switches and also the tristate option for one of the two cross-coupled inverters. In a straightforward realization of the edge-triggered flip-flop according to FIG. 3, four additional transistors may be used for implementing the four switches and two additional transistors may be used for implementing the tristate option, thus resulting in an additional circuitry outlay of 6 transistors in total.

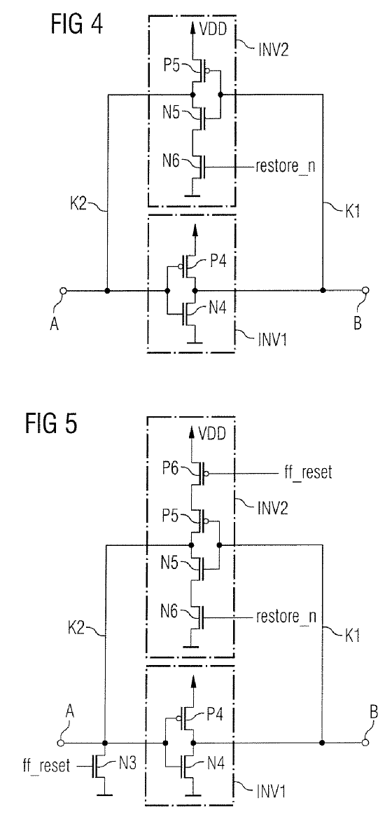

FIG. 4 illustrates a first exemplary implementation of the cross-coupled inverters INV1 and INV2 from FIG. 3, wherein the implementation of the tristate option uses a single additional NMOS transistor N6 which decouples the output of the inverter INV2 from the ground node VSS if the signal restore_n is at VSS. If the storage node K2 is initialized to VSS via the switch SW2, the input of the inverter INV2 may be at VDD if the inverters INV1 and INV2 are active. It is therefore possible to preclude the activation of the PMOS transistor P5 of the CMOS inverter INV2 so that it is possible to dispense with a PMOS transistor arranged at the source terminal of P5 analogously to N6 and serving for decoupling the output of the inverter INV2 from the positive operating voltage node VDD.

If the storage node K2 is initialized to VDD, an additional PMOS transistor instead of the NMOS transistor N6 may be used for implementing the tristate option (not illustrated).

For the case where an intervention for resetting the multivibrator (reset function) is provided anyway for the bistable multivibrator, the additional circuitry outlay can be reduced further in comparison with a customary edge-triggered latch with a reset function. FIG. 5 illustrates a second exemplary embodiment of the implementation of the cross-coupled inverters INV1 and INV2, which is based on the exemplary embodiment illustrated in FIG. 4. In this case, the two additional transistors P6 and N3 are provided for implementing the reset function, said transistors being controlled by means of the signal ff_reset. If the signal ff_reset is at VDD, the transistor N3 is in the on state and the node K2 is at VSS. The turned-off transistor P6 simultaneously prevents the inverter INV2 from pulling the node K2 to VDD, that is to say prevents the inverter INV2 from operating against N3.

The NMOS transistor N3 furthermore performs the function of the switch SW2 from FIG. 2, so that in FIG. 5 the transistor N6 constitutes additional circuitry outlay. Therefore, a latch according to one embodiment of the invention with a reset function which is based on FIG. 5 comprises four additional transistors (SW1, SW3, SW4 and N6) and also an additional single programmable resistance element in comparison with a customary latch with a reset function. Such a realization therefore has a lower additional circuitry outlay than the solution which is described in the document US 2004/0141363 A1 and which comprises a total of four additional transistors (the two coupling transistors described therein have to be replaced by two transmission gates for robust operation), and two additional programmable resistance elements.

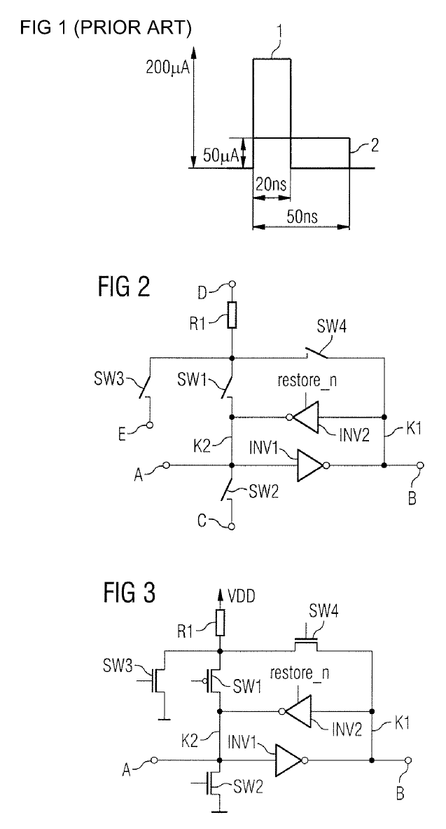

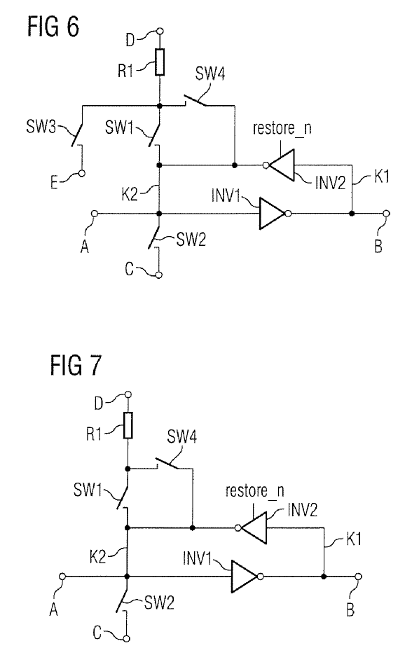

FIG. 6 illustrates a simplified basic circuit diagram—as an alternative to FIG. 2—for a second plurality of exemplary embodiments of the non-volatile memory cell according to one embodiment of the invention, four different exemplary embodiments being provided in accordance with Table 1. The circuit in accordance with FIG. 6 operates similarly to the circuit illustrated in FIG. 2. One possible difference between the circuits illustrated in FIG. 6 and FIG. 2 is that in FIG. 6 the switch SW4 is connected to the storage node K2 instead of to the storage node K1. Furthermore, in FIG. 6 the switch SW3 is used to initialize the resistance element with low resistance instead of high resistance as in FIG. 2. Accordingly, the switch SW4 serves to program the resistance element R1 in high-resistance fashion instead of low-resistance fashion during the save operation, if the potential of the storage node K2 differs from that of the node D. As can be seen from FIG. 1, a higher current intensity may be used for programming the high-resistance state than for programming the low-resistance state. Therefore, the transistor for implementing the switch SW4 is generally wider in FIG. 6 than in FIG. 2. This may be associated with the parasitic elements connected with the switch SW2 being larger in FIG. 6 than in FIG. 2. Moreover, the parasitic loading of the storage nodes K1 and K2 may be more asymmetric in FIG. 6 than in FIG. 2. Therefore, in some cases, the concept illustrated in FIG. 2 may be used instead of the concept illustrated in FIG. 6.

FIG. 7 illustrates a simplified basic circuit diagram—as an alternative to FIG. 2 and FIG. 6—for a third plurality of exemplary embodiments of the non-volatile memory cell according to one embodiment of the invention, four fundamentally exemplary embodiments being provided in accordance with Table 1. One possible difference between the basic circuit diagram in FIG. 6 and FIG. 7 is that in FIG. 7 the separate switch SW3 for the initialization of the resistance element has been obviated. The resistance element R1 is initialized via the switch SW4 (initialization via SW1 may also be utilized). However, in some cases, the resistance element R1 may be initialized when the node D and the storage node S2 have different potentials. There are a number of possibilities for providing this during the initialization of the resistance element R1. Different potentials for the node D and the storage node K2 are present, for example, when the latch is reset. In this case, by way of example, the node D is at VDD, while the storage node K2 is at VSS. In some cases, the initialization of the resistance element R1 may be accompanied by a loss of information of the bistable multivibrator. In this case, therefore, the resistance element R1 may be initialized temporally before an item of information is stored in the bistable multivibrator, for example when the latch is switched on. As an alternative, provision may be made for changing the potential at the node D. By way of example, the node is firstly put at VDD in a first switch position and is then put at VSS in a second switch position. In this case, independently of the storage state of the bistable multivibrator, the node D and the storage node K2 may have different potentials either in the first switch position or in the second switch position. It should be noted that the switch SW3 can also be obviated in an analogous manner in FIG. 2.

It should be noted that it is also possible in accordance with the application for the separate switches SW1 and SW4 illustrated in FIG. 7 to be replaced by a single switch.

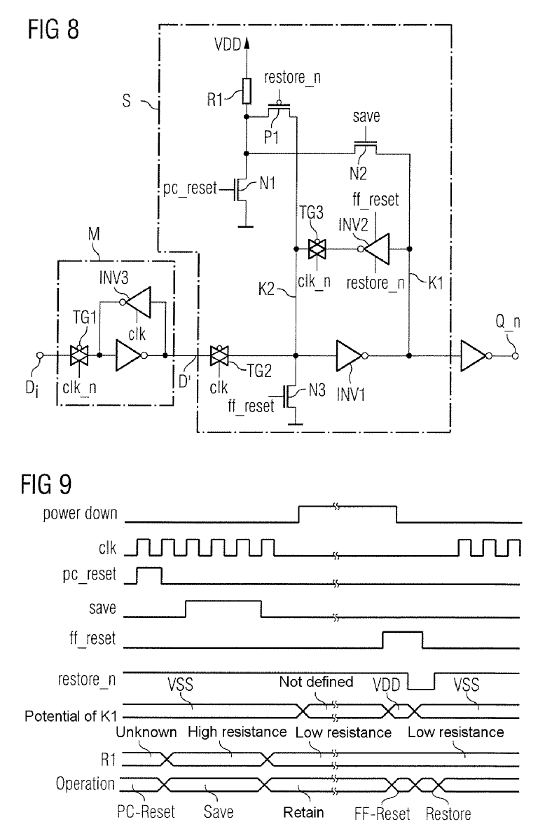

FIG. 8 illustrates a first exemplary embodiment of the memory cell in the form of a retention master-slave D-type flip-flop. The flip-flop comprises a master stage M (master latch) and a slave stage S (slave latch), both stages comprising a bistable multivibrator in the form of two cross-coupled inverters for information storage. The slave stage S is based on the circuits illustrated in FIG. 3 and FIG. 5 and comprises a resistor R1 for saving the binary information stored in the slave stage S. The transistors N1, N2 and P1 correspond to the transistors SW3, SW4 and SW1, respectively, illustrated in FIG. 3. The flip-flop is controlled by means of the clock signals clk and clk_n (inverted clock), which are received by the transmission gates TG1 to TG3 and also by the inverter INV3 having an output that can be switched in high-resistance fashion.

The flip-flop can be reset asynchronously by means of the signal ff_reset if the signals restore_n and save are at VDD and VSS, respectively.

The customary operation of the flip-flop will be described first, the signals ff_reset, restore_n, save and pc_reset being at VSS, VDD, VSS and VSS, respectively. If the clock signal clk changes from high to low, the new data bit at the data input D1 is forwarded in inverted form to the output D′ of the master stage M, the output of the inverter INV3 being switched in high-resistance fashion and the multivibrator of the master stage M not storing any information. The master stage M and the slave stage S are decoupled from one another by means of the transmission gate TG2. The bistable multivibrator of the slave stage S retains the previous data bit. If the clock signal clk switches from low to high, the flip-flop is isolated from the input D₁ by means of the transmission gate TG1. The new data bit at the output D′ of the master stage M is forwarded via the turned-on transmission gate TG2 to the data output Q_n of the flip-flop, the bistable multivibrator of the master stage M retaining the new data bit.

The process of saving the information stored in the multivibrator of the slave stage and the retrieval of the saved information are described below in conjunction with FIG. 9. The digital control signals pc_reset, ff_reset, save and restore_n serve for controlling the data saving and for retrieving the saved information.

At the beginning of saving, the power-down mode is still deactivated, that is to say the corresponding signal power_down is at VSS. Before the binary information of the multivibrator is saved, the programmable resistance element R1 is put into a defined state (see PC reset operation in FIG. 9). For this purpose, the signal pc_reset that drives the transistor N1 changes from low to high (see FIG. 9). This initiates a current through the resistance element R1 and the transistor N1, so that the resistance element R1 acquires a high resistance and amorphous state.

During the subsequent save operation, the signal save is changed over from low to high, so that the storage node K1 is connected to the resistance element R1 via the turned-on transistor N2. For the case where the storage node K1 is at VDD, no current flows through the resistance element R1 so that the resistance element R1 remains in the high-resistance state. If the storage node K1 is at VSS (as illustrated in FIG. 9), a current flows through the resistance element R1, so that the resistance element R1 is put into the low-resistance state (polycrystalline state). The state of the multivibrator of the slave stage S is now saved in non-volatile fashion in the resistor R1. The supply voltage of the flip-flop is subsequently switched off, the signal power_down changing over to high.

While the supply voltage of the flip-flop is switched off, the saved information is retained in the resistor R1. Retrieval of the saved information may occur when the clock signal clk to be is at VSS, so that the transmission gate TG2 turns off and decouples the storage node K2 from the output of the master stage M. The flip-flop is switched on again (power_down is low) and the signal ff_reset switches to VDD, so that the flip-flop is reset into a fixed state (see FF reset operation in FIG. 9). In this case, the storage node K2 is put at VSS by means of the transistor N3. The signal restore_n is subsequently put at VSS, so that the positive feedback of the multivibrator within the slave stage S is interrupted. The storage node K2 may be driven by the turned-on coupling transistor P1 which connects the storage node K2 to VDD via the resistance element R1. The potential at the storage node rises depending on the resistance value of the resistance element R1. In this case, the total change in potential depends on the pulse duration during which the signal restore_n is at VSS. Given a suitable choice of the pulse duration, the storage node K2 is subjected to charge reversal to a potential close to VDD if the resistance element has low resistance. As an alternative, the potential of the storage node remains close to VSS if the programmable resistance element has high resistance.

The charge-reversal process can be described to a first approximation by means of an RC equivalent circuit diagram. A value of C=5 fF for the capacitance of the storage node K2 and a total resistance formed by the resistance element R1 and the transistor P1 of R=20 kΩ (if R1 has low resistance) or R=1 MΩ (if R1 has high resistance) are assumed in this case, by way of example. The value of the time constant τ=RC of the charge-reversal process and therefore results as τ=100 ps, if R1 has low resistance or as τ=5 ns, if R1 has high resistance. Given a pulse duration of 500 ps, the value of the potential at the end of the charge-reversal process reaches more than 0.9VDD, if R1 has low resistance or less than 0.05VDD, if R1 has high resistance. As soon as the signal restore_n has been changed over to VDD at the end of the pulse duration, the positive feedback of the multivibrator of the slave stage S is activated, so that the multivibrator toggles in the corresponding direction depending on the voltage at the storage node K2.

In an analogous manner to the flip-flop illustrated in FIG. 8, the resistance element R1 may be assigned to the master stage M instead of to the slave stage S, so that the information stored in the master stage M is saved by means of the resistance element R1.

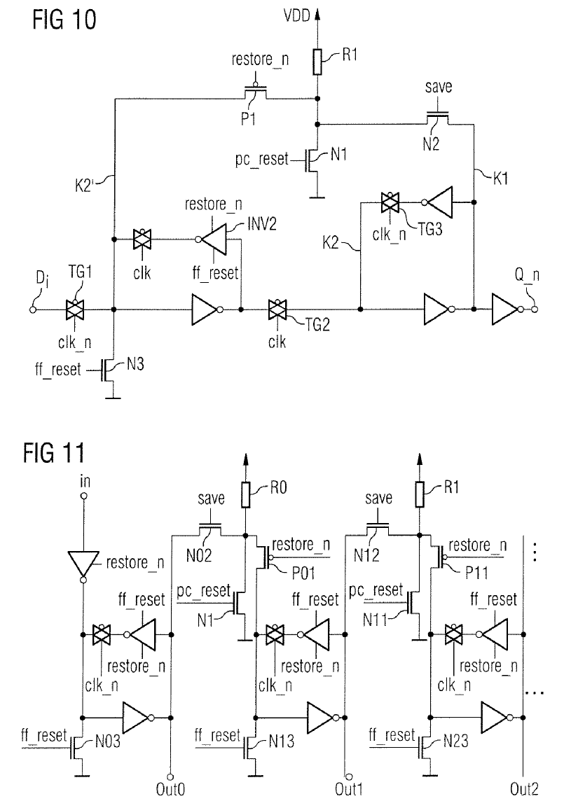

FIG. 10 illustrates an embodiment as an alternative to FIG. 8 for a retention master-slave D-type flip-flop. Circuit elements and signals from FIG. 8 and FIG. 10 that are provided with identical reference symbols correspond to one another. In FIG. 10, in the same way as in FIG. 8, the information at the storage node K1 of the slave stage is saved in the resistance element R1. In contrast to the circuit illustrated in FIG. 8, however, in FIG. 10, the saved information is coupled into the storage node K2′ of the master stage during retrieval.

FIG. 11 illustrates an exemplary embodiment of the shift register in accordance with another embodiment of the invention. In configurable circuits, shift registers are often used to read in a sequence of binary values serially. Two latches may be used for a stage of a shift register: a first latch, which receives the value of the preceding stage, and a second latch which drives the value received by the succeeding stage. The first and second latches respectively correspond to the master and slave stages of a master-slave flip-flop. A shift register which, by way of example stores configuration data in a non-volatile manner can be realized by means of a series circuit comprising the above-described retention master-slave flip-flops according to one embodiment of the invention in accordance with FIG. 8 or FIG. 10. In order to reduce the area usage of the shift register, in the case of the shift register illustrated in FIG. 11, the slave stage is in each case may include the programmable resistance element R1 plus the transistors Ni2 and Ni1 for the programming of the resistance element and also the transistors Ni3 and Pi1 for the read-out of the resistance element.

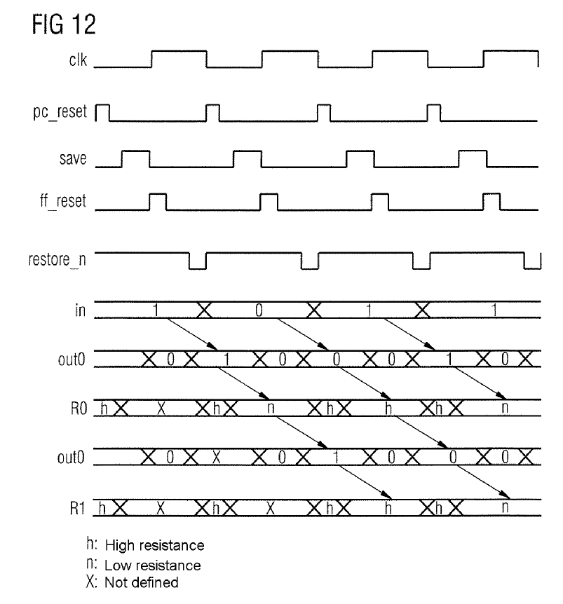

FIG. 12 indicates a signal diagram for the shift register illustrated in FIG. 11. The serial data signal is fed in via the input in. The signals clk, clk_n, ff_reset, restore_n and pc_reset and save control the shifting of the data through the shift register. In this case, one data bit per clock period is advanced by an output outi.

While the foregoing is directed to embodiments of the present invention, other and further embodiments of the invention may be devised without departing from the basic scope thereof, and the scope thereof is determined by the claims that follow.

1. A non-volatile memory cell, comprising:
a volatile memory cell with one or more storage nodes for storing an item of binary information in the form of the potential value of a first storage node, and
a single resistance element having a binary programmable resistance value for non-volatile saving of the binary information stored in the volatile memory cell;
storage circuitry configured to store the binary information in the resistance element, wherein the storage circuitry is configured to change the resistance value to a resistance value corresponding to the potential of the first storage node; and
load circuitry configured to load the binary information saved in the form of the resistance value.

2. The non-volatile memory cell of claim 1, wherein the load circuitry configured to load the binary information is configured to define the potential value of a second storage node of the non-volatile memory cell or of another identical non-volatile memory cell in a manner dependent on the resistance value.

3. The non-volatile memory cell of claim 2, wherein the load circuitry comprises:
first initialization circuitry configured to initialize the potential of the second storage layer with a fixed value.

4. The non-volatile memory cell of claim 3, wherein the storage circuitry configured to store the binary information comprises:
second initialization circuitry configured to initialize the resistance value to a specific value of the binary programmable values.

5. The non-volatile memory cell of claim 3, wherein the volatile memory cell comprises a bistable multivibrator in the form of two cross-coupled inverters.

6. The non-volatile memory cell of claim 5, wherein the volatile memory cell is configured in such a way that the second storage node is electrically connected to the output of an inverter of the volatile memory cell of the non-volatile memory cell or of another identical memory cell, wherein an output of the inverter is configured to be switched in high-resistance fashion or decoupled from the second storage node.

7. The non-volatile memory cell of claim 6, wherein the two cross-coupled inverters are CMOS inverters each having an NMOS transistor and a PMOS transistor;
wherein the first initialization circuitry configured to initialize the potential of the second storage node, while initializing the potential, connects the second storage node to a ground node in a first configuration or to a positive operating voltage node in a second configuration, while the output of the inverter which is configured to be switched in high-resistance fashion is switched in high-resistance fashion, and
wherein, in the inverter which is configured to be switched in high-resistance fashion on the output side, only a single additional transistor is provided for switching the inverter output into a high-resistance state, said transistor being in the first configuration an NMOS transistor, the source-drain path of which is arranged between the ground node and source terminal of the NMOS transistor and for the same inverter, and which decouples the ground node from the source terminal of the NMOS transistor of the inverter in the case of a high-resistance output, and being in the second configuration a PMOS transistor, the source-drain path of which is arranged between the positive operating voltage node and the source terminal of the PMOS transistor of the same inverter, and which decouples the positive operating voltage node from the source terminal of the PMOS transistor of the inverter in the case of a high-resistance output.

8. The non-volatile memory cell of claim 4, wherein the storage circuitry configured to store the binary information comprises a first switch which is configured to electrically connect the first storage node to the resistance element.

9. The non-volatile memory cell of claim 8, wherein the storage circuitry configured to store the binary information comprises the first switch which is configured to electrically decouple the first storage node from the resistance element.

10. The non-volatile memory cell of claim 9, wherein the load circuitry configured to load the saved binary information comprises a second switch which electrically connects the second storage node to the resistance element.

11. The non-volatile memory cell of claim 10, wherein the load circuitry configured to load the saved binary information comprises the second switch which electrically decouples the second storage node from the resistance element.

12. The non-volatile memory cell of claim 11, wherein the first switch and the second switch are two separate switches.

13. The non-volatile memory cell of claim 4, wherein the second initialization circuitry configured to initialize the resistance value comprises a third switch which electrically connects the resistance element to a first node having a fixed potential.

14. The non-volatile memory cell of claim 13, wherein the second initialization circuitry configured to initialize the resistance value comprises a third switch which electrically decouples the resistance element from the first node having a fixed potential.

15. The non-volatile memory cell of claim 14, wherein the first switch and the third switch are two separate switches.

16. The non-volatile memory cell of claim 3, wherein the first initialization circuitry configured to initialize the potential of the second storage node comprises a fourth switch in the form of a MOS transistor which either:
electrically connects the second storage node to a second node having a fixed potential or decouples the second storage node from the second node having a fixed potential.

17. The non-volatile memory cell of claim 10, wherein the load circuitry configured to load the binary information comprises a fourth switch in the form of a MOS transistor, which, in a closed state, electrically connects the second storage node to a second node having a fixed potential, the potential at the second storage node corresponding to the binary information when the second switch and fourth switch are closed.

18. The non-volatile memory cell of claim 17, wherein the volatile memory cell is configured to be reset into a specific state, the fourth switch being used for resetting the volatile memory cell.

19. The non-volatile memory cell of claim 8, wherein
the first node and the second node include a fixed potential correspond to the ground node,
the resistance element is connected to the positive operating voltage node, and
the first switch, the second switch, the third switch, and the fourth switch are implemented in the form of an NMOS transistor, PMOS transistor, NMOS transistor and NMOS transistor, respectively.

20. The non-volatile memory cell of claim 8, wherein the first node and the second node include a fixed potential correspond to the positive operating voltage node, and the resistance element is connected to the ground node, and the first switch, the second switch, the third switch, and the fourth switch are implemented in the form of a PMOS transistor, NMOS transistor, PMOS transistor and PMOS transistor, respectively.

21. The non-volatile memory cell of claim 4, wherein
the second initialization circuitry configured to initialize the resistance value is configured to initialize the resistance value to the larger of the two programmable values.

22. The non-volatile memory cell of claim 4, wherein
the second initialization circuitry configured to initialize the resistance value is configured to initialize the resistance value to the smaller of the two programmable values.

23. The non-volatile memory cell of claim 8, wherein
the first switch is further configured to initialize the resistance value as part of the second initialization circuitry configured to initialize resistance value.

24. The non-volatile memory cell of claim 1, wherein
the non-volatile memory cell constitutes a master-slave flip-flop having a master stage and a slave stage, the volatile memory cell comprising a total of two bistable multivibrators and the master stage comprising the first bistable multivibrator and the slave stage comprising the second bistable multivibrator.

25. The non-volatile memory cell of claim 24, wherein
the first storage node and the second storage node are nodes of different multivibrators, wherein the first storage node a node of the second multivibrator and the second storage node is a node of the first multivibrator.

26. The non-volatile memory cell of claim 2, further comprising:
a master-slave flip-flop having a master stage and a slave stage,
wherein the volatile memory cell comprises a single bistable multivibrator,
wherein the master stage comprises the bistable multivibrator, and
wherein the slave stage comprises the resistance element, the storage circuitry, and the load circuitry.

27. The non-volatile memory cell of claim 1, wherein
the phase state of the resistance element is changed during the programming of the resistance value, the resistance element having
a first resistance value in an amorphous state and,
a second resistance value in a polycrystalline state, the first resistance value being greater than the second resistance value.

28. A shift register, comprising:
a plurality of series-connected non-volatile memory cells, each comprising:
a volatile memory cell with one or more storage nodes for storing an item of binary information in the form of the potential value of a first storage node;
a single resistance element having a binary programmable resistance value for non-volatile saving of the binary information stored in the volatile memory cell;
storage circuitry configured to store the binary information in the resistance element, wherein the storage circuitry is configured to program the resistance value to a resistance value corresponding to the potential of the first storage node; and
load circuitry configured to load the binary information saved in the form of the resistance value, wherein, for each non-volatile memory cell, the load circuitry configured to load the binary information defines the potential value of a second storage node of the memory cell connected downstream of the respective memory cell in a manner dependent on the resistance value.
